(19) United States
(12) Patent Application Publication
(10) Pub. No.: US 2013/0141846 A1
(43) Pub. Date: Jun. 6, 2013

(54) Backplane and Liquid Crystal Display Device

(71) Applicant: Gege Zhou, Shenzhen (CN)

(72) Inventor: Gege Zhou, Shenzhen (CN)

(21) Appl. No.: 13/378,123

(22) PCT Filed: Dec. 6, 2011
(86) PCT No.: PCT/CN2011/083535

§ 371 Date: Dec. 14, 2011

(30) Foreign Application Priority Data
Dec. 2, 2011 (CN) 2011103960038

(51) Int. Cl. H05K 7/02; H05K 7/18

(52) U.S. Cl. 361/679.01; 211/26

(57) ABSTRACT

The present invention discloses a backplane and an LCD device, the backplane is formed by jointing of at least two sub-backplanes, the joint of the sub-backplanes are provided with multiple vertical enhanced ribs perpendicular to the joint section of the joint, and the vertical enhanced ribs are arranged along the joint section. Because the backplane of the present invention is formed by jointing of multiple sub-backplanes, the large stamping equipment or the large die is not needed for the backplane, thus the production cost of the backplane is reduced; in addition, multiple sub-backplanes are jointed in the present invention, therefore, the side of the backplane on which the heat is high can be made of materials with good heat dissipation performance, and for the side on which the heat is lower, the backplane can be made of ordinary materials with sufficient intensity, thereby reducing the cost; further, the present invention also adds multiple vertical enhanced ribs perpendicular to the joint section on the joint of the backplane, thus the intensity of the joint and the vertical intensity of the backplane are increased, thereby increasing the flatness of the backplane, and improving the display quality of the LCD device.

### TECHNICAL FIELD

The present invention relates to the field of liquid crystal displays, and more particularly to a backplane and a Liquid Crystal Display (LCD) device.

### BACKGROUND

All the LCD modules produced in batches at present use integral backplanes. Generally, the backplanes are made of the same material including the aluminum plate, the iron plate or the plastic cement, and are integrally formed in the mode of metal stamping or plastic injection, causing heavy products and high material cost of the products. Large products needs larger stamping equipment, therefore, the cost is high, the corresponding die size is large, the structure is complicated, and the die cost is high. If the whole backplane is made of the iron plate, a heat dissipation element shall be added, thus the cost is increased; if the whole backplane is made of the aluminum plate, the radiating element is not added and used; although the heat conduction effect of the aluminum plate is better than that of the iron plate, only a part of the backplane performs a radiation action and the other part performs a supporting action instead of the radiation action; the price of the aluminium plate is high, thus the material cost is high.

### SUMMARY

The aim of the present invention is to provide a backplane with low manufacturing cost and high strength, and an LCD device.

The aim of the present invention is achieved by the following technical schemes: a backplane formed by jointing of at least two sub-backplanes, the joint of the sub-backplanes are provided with multiple vertical enhanced ribs perpendicular to the joint section of the joint, and the vertical enhanced ribs are arranged along the joint section.

Preferably, the multiple vertical enhanced ribs are arranged at equal intervals along the joint, so that the intensity of the joint of the backplane is uniform, thereby avoiding the difference between the part of stresses resulting in the transformation of the backplane.

Preferably, the enhanced ribs also includes the transverse enhanced ribs against the vertical enhanced ribs and perpendicular to the vertical enhanced ribs. The transverse intensity of the backplane can be increased by the transverse enhanced ribs.

Preferably, the joint between the two mutually jointed between two sub-backplanes are respectively provided with the vertical enhanced ribs with The same number, the two corresponding vertical enhanced ribs between the two sub-backplanes are mutually nested, overlapped and jointed. The enhanced ribs of the two sub-backplanes are overlapped to increase the intensity of the joint.

Preferably, it is have a gap at the edges between two vertical enhanced ribs mutually nested and overlapped, thereby facilitating the installation of the two sub-backplanes, and ensuring the installation accuracy and that the no locally different stress is produced after the riveting.

Preferably, the nested and overlapped area of the two corresponding vertical enhanced ribs is less than half the length of the vertical enhanced ribs. In case that the installation intensity is ensured, the usage amount of the material is reduced as much as possible.

Preferably, the backplane is formed by jointing of at least two sub-backplanes of different material. The corresponding material is selected in accordance with the function of the backplane to achieve the aim of cut down the material cost.

Preferably, the backplane is formed by jointing of two sub-backplanes of different material. Only two sub-backplanes are used to reduce the processing step of the joint.

Preferably, the sub-backplane on the side on which the LED light bar is required to be arranged is the aluminum structure. The heat of the sub-backplane on the side on which the LED is required to be arranged is higher, thus the aluminum material with better heat dissipation effect can be selected.

Preferably, the multiple enhanced ribs are provided with the riveting points, and the sub-backplanes are riveted through the riveting points. The riveting points are arranged on the enhanced ribs, so that the enhanced ribs are connected, thereby improving the vertical reinforcing function of the vertical enhanced ribs.

Preferably, each of the multiple enhanced ribs is provided with two riveting points vertically arranged, thereby increasing the joint intensity of the two enhanced ribs mutually overlapped.

An LCD device, wherein the LCD device comprises the backplane.

Because the backplane of the present invention is formed by jointing of multiple sub-backplanes, the large stamping equipment or the large mold is not needed for the backplane during production, thus the production cost of the backplane is reduced; in addition, because multiple sub-backplanes are jointed in the present invention, the side of the backplane on which the heat is high can be made of materials with good heat dissipation performance, and for the side on which the heat is lower, the backplane can be made of ordinary materials with sufficient intensity, thereby reducing the material cost; further, the present invention also adds multiple vertical enhanced ribs perpendicular to the joint section on the joint of the backplane, thus the intensity of the joint and the vertical intensity of the backplane are increased, thereby increasing the flatness of the backplane, and improving the display quality of the LCD device.

### BRIEF DESCRIPTION OF FIGURES

FIG. 1 is a structural diagram of the first sub-backplane of a backplane of an example of the present invention;

FIG. 2 is a structural diagram of the second sub-backplane of a backplane of an example of the present invention;

FIG. 3 is a structural diagram of a backplane of an example of the present invention;

FIG. 4 is a diagram of the A-A section of FIG. 3;

FIG. 5 is a diagram of the B-B section of FIG. 3.

Wherein: 100. First sub-backplane, 110. First vertical enhanced ribs, 120. First transverse enhanced ribs; 111. Riveting points, 150 Space, 200. Second sub-backplane, 210. Second vertical enhanced ribs, 220. Second transverse enhanced ribs.

### DETAILED DESCRIPTION

The present invention will be further described in accordance with the figures and the preferred examples.

The applicant applied a backplane of a backlight module, a backlight module and an LCD device on 12th of October; the application number is 201110308489.5. The application discloses a backplane structure formed by a heatsink plate and a supporting plate, as follows: an LCD device comprises a backlight module; the bottom of the backlight module is provided with a backplane for supporting internal devices and sealing the module and providing necessary protections. The backplane of the backlight module comprises a heatsink plate and a supporting plate connected with the heatsink plate, wherein the heat conductivity of the heatsink plate is larger than that of the supporting plate. The heatsink plate is made of the material with good heat dissipation performance, in addition to basic functions of the backplane, the heatsink plate has a good heat dissipation effect, and the supporting plate is mainly used for basic supporting functions. As shown in FIG. 1 to FIG. 4, a backplane of the backlight module of the present invention comprises: a first sub-backplane 100 and a second sub-backplane 200, wherein the joint between the first sub-backplane 100 and the second sub-backplane 200 are respectively provided with the first vertical enhanced ribs 110 and the second vertical enhanced ribs 210 which are perpendicular to the joint section of the joint. The structure of the first sub-backplane 100 of the present invention and the structure of heatsink plate of the application document are of the same function, and the structure of the second sub-backplane 200 and the structure of the supporting plate are of the same function. However, the functional differentiation of the multiple sub-backplanes of the present invention is not limited to the two main functions of heat dissipation and supporting, in accordance with more functional requirements and the simplification of the process or the control of the material cost, the present invention shall also design the number of corresponding sub-backplanes i.e. corresponding functions to achieve the optimal design.

FIG. 1 to FIG. 4 show the preferred examples of the present invention:

FIG. 1 shows the first sub-backplane 100 of an example of the present invention, wherein at the joint of the first sub-backplane 100, multiple first vertical enhanced ribs 110 are arranged side by side along the joint, and multiple first vertical enhanced ribs 110 which are perpendicular to the joint section are vertically arranged; the first transverse enhanced ribs 120 are arranged on positions against the first vertical enhanced ribs 110, and the first transverse enhanced ribs 120 are parallel to the joint section to increase the transverse intensity of the joint of the backplane, while the vertically arranged vertical enhanced ribs 110 are used not only to increase the vertical intensity of the joint, but also to increase the intensity of the riveting points.

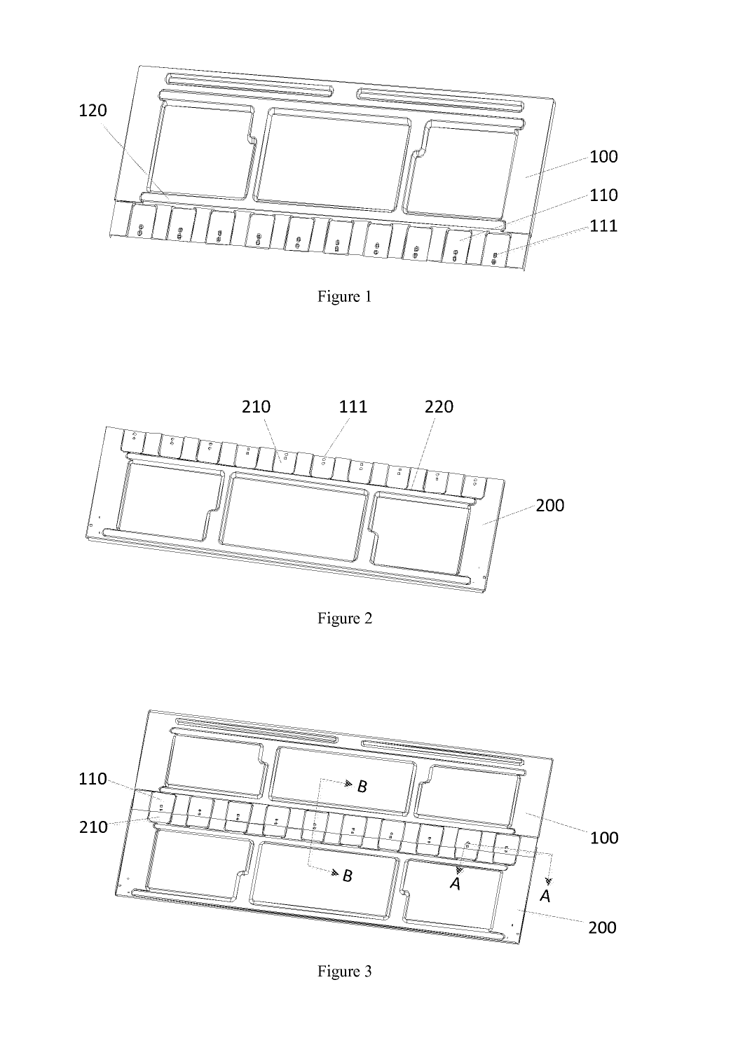

FIG. 2 shows the second sub-backplane 200 of an example of the present invention, wherein at the joint of the second sub-backplane 200, multiple second vertical enhanced ribs 210 correspondingly matching with the first vertical enhanced ribs 110 of FIG. 1 are similarly arranged side by side along the joint, and multiple second vertical enhanced ribs 210 which are perpendicular to the joint section are vertically arranged; the second transverse enhanced ribs 220 are arranged on positions against the second vertical enhanced ribs 210, and the second transverse enhanced ribs 220 are parallel to the joint section to increase the transverse intensity of the joint of the second sub-backplane 200, while the vertically arranged second vertical enhanced ribs 210 are used not only to increase the vertical intensity of the joint, but also to increase the intensity of the riveting points.

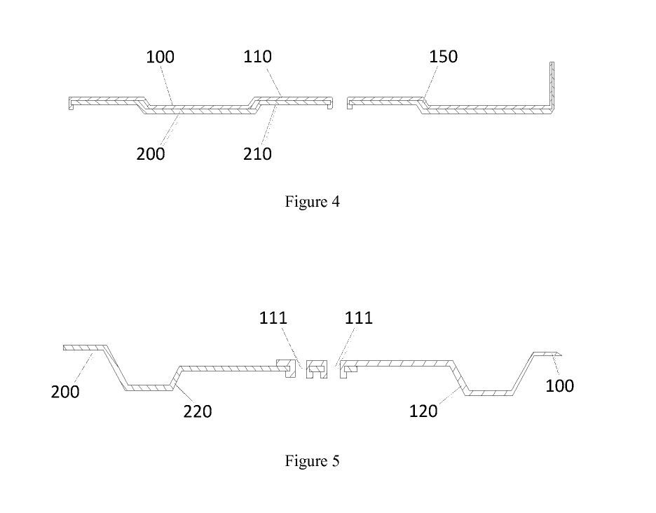

FIG. 3 shows a backplane formed by jointing, the backplane is formed by jointing of the first sub-backplane 100 shown in FIG. 1 and the second sub-backplane 200 shown in FIG. 2. As shown in the figure, the first sub-backplane 100 and the second sub-backplane 200 are riveted at the joint section through the riveting points on the vertical reinforcing steels arranged on the first sub-backplane 100 and the second sub-backplane 200. The size of the first vertical reinforcing steels 110 is larger than that of the second vertical reinforcing steels 210, however, the first vertical reinforcing steels 110 and the second vertical reinforcing steels 210 are of the same shape, and after the jointing of the first sub-backplane 100 and the second sub-backplane 200, the second vertical reinforcing steels 210 are nested into the first vertical reinforcing steels 110, and the first vertical reinforcing steels 110 and the second vertical reinforcing steels 210 are jointed and overlapped. The backplane is vertically reinforced through the vertical reinforcing steels on the backplane, as shown in FIG. 4, the first vertical reinforcing steels 110 and the second vertical reinforcing steels of the two sub-backplanes are mutually nested, overlapped and jointed, thereby increasing the intensity of the joint; as shown in FIG. 1 and FIG. 2, the riveting points 111 are arranged on the reinforcing steels, which is equivalent to that the vertical reinforcing steels are mutually connected, thereby increasing the intensity of the joint and increasing the whole backplane in the vertical direction; the example also uses the first transverse reinforcing steels 120 and the second transverse reinforcing steels 220 shown in FIG. 1, FIG. 2 and FIG. 5 to increase the transverse intensity of the backplane; the backplane is reinforced through the transverse reinforcing steels and the vertical reinforcing steels, thus the flatness of the backplane is increased and the display quality of the LCD device is improved.

In the example of the present invention, the first vertical reinforcing steels 110 and the second vertical reinforcing steels 210 are arranged at equal distance on the joint of the backplane along the joint, in order to achieve the uniform reinforcing state, and avoid uniform stress produced by the backplane.

In addition, in the example, the nested and overlapped area of the two corresponding vertical enhanced ribs is less than half the length of the vertical enhanced ribs; in case that the intensity requirement is ensured, the overlapped area is reduced as much as possible, thereby reducing the usage amount of the material. The gap is remained at the edges of the two corresponding vertical enhanced ribs mutually nested and overlapped, as shown in FIG. 4, the second vertical enhanced ribs 210 are nested into the first vertical enhanced ribs 110, and the space 150 is remained at the joint edge, thereby facilitating the jointing and the assembly of the two sub-backplanes; in case of the gap, the jointing accuracy and no stress deformation shall be ensured. As shown in FIG. 5, each reinforcing steel is provided with two vertically arranged riveting points 111 to ensure the intensity of the jointing points mutually jointed and the joint intensity of the vertical enhanced ribs.

Further, the present invention is formed by jointing of multiple su-backplanes, for example, two sub-backplanes are selected to be jointed in the example of the present invention, therefore, in accordance with the structure and characteristics of the liquid crystal panel, because one side of the liquid crystal panel is provided with components like LEDs and the heat is high, the sub-backplane made of materials with good heat dissipation effect may be used on the side. In the example of the present invention, if the aluminum material is used for the first sub-backplane 100, the second sub-backplane may use material meeting the requirement of the intensity like iron plate. For material with good heat dissipation effect like aluminium plate, the price is usually high; the present invention increases the material cost of the backplane by reducing the usage of the aluminum material.

The present invention is described in detail in accordance with the above contents with the specific preferred examples. However, this invention is not limited to the specific examples. For the ordinary technical personnel of the technical field of the present invention, on the premise of keeping the conception of the present invention, the technical personnel can also make simple deductions or replacements, and all of which should be considered to belong to the protection scope of the present invention.

1. A backplane formed by jointing of at least two sub-backplanes, the joint of the sub-backplanes are provided with multiple vertical enhanced ribs perpendicular to the joint section of the joint, and the vertical enhanced ribs are arranged along the joint section.

2. The backplane of claim 1, wherein the multiple vertical enhanced ribs are arranged at equal intervals along the joint.

3. The backplane of claim 2, wherein the enhanced ribs also includes the transverse enhanced ribs against the vertical enhanced ribs and perpendicular to the vertical enhanced ribs.

4. The backplane of claim 2, wherein the joint between the two mutually jointed sub-backplanes are respectively provided with the vertical enhanced ribs with the same number, the two corresponding vertical enhanced ribs between the two sub-backplanes are mutually nested, overlapped and jointed.

5. The backplane of claim 4, it is have a gap at the edges of the two vertical enhanced ribs mutually nested and overlapped.

6. The backplane of claim 4, wherein the nested and overlapped area of the two corresponding vertical enhanced ribs is less than half the length of the vertical enhanced ribs.

7. The backplane of claim 1, wherein the backplane is formed by jointing of at least two sub-backplanes of different material.

8. The backplane of claim 7, wherein the backplane is formed by jointing of two sub-backplanes of different material.

9. The backplane of claim 8, wherein the sub-backplane on the side on which the LED light bar is required to be arranged is the aluminum structure.

10. The backplane of claim 1, wherein the multiple enhanced ribs are provided with the riveting points, and the sub-backplanes are riveted through the riveting points.

11. The backplane of claim 10, wherein each of the multiple enhanced ribs is provided with two riveting point vertically arranged.

12. An LCD device comprises the backplane of claim 1, the backplane is formed by jointing of at least two sub-backplanes, the joint of the sub-backplanes are provided with multiple vertical enhanced ribs perpendicular to the joint section of the joint, and the vertical enhanced ribs are arranged along the joint section.

13. The LCD device of claim 12, wherein the multiple vertical enhanced ribs are arranged at equal intervals along the joint.

14. The LCD device of claim 13, wherein the enhanced ribs also includes the transverse enhanced ribs against the vertical enhanced ribs and perpendicular to the vertical enhanced ribs.

15. The LCD device of claim 13, wherein the joint between the two mutually jointed sub-backplanes are respectively provided with the vertical enhanced ribs with the same number, the two corresponding vertical enhanced ribs between the two sub-backplanes are mutually nested, overlapped and jointed.

16. The LCD device of claim 15, it is have a gap at the edges of the two vertical enhanced ribs mutually nested and overlapped.

17. The LCD device of claim 15, wherein the nested and overlapped area of the two corresponding vertical enhanced ribs is less than half the length of the vertical enhanced ribs.

18. The LCD device of claim 12, wherein the backplane is formed by jointing of at least two sub-backplanes of different material.

19. The LCD device of claim 18, wherein the backplane is formed by jointing of two sub-backplanes of different material.

20. The LCD device of claim 19, wherein the sub-backplane on the side on which the LED light bar is required to be arranged is the aluminum structure.

21. The LCD device of claim 12, wherein the multiple enhanced ribs are provided with the riveting points, and the sub-backplanes are riveted through the riveting points.

22. The LCD device of claim 21, wherein each of the multiple enhanced ribs is provided with two riveting point vertically arranged.
